(19) United States
(12) Patent Application Publication
(10) Pub. No.: US 2026/0282554 A1
(43) Pub. Date: Sep. 17, 2026

(54) PRODUCTION METHOD OF SEMICONDUCTOR DEVICE

(71) Applicant: Tokyo Electron Limited, Tokyo (JP)

(72) Inventors: Toshinori FUKAI, Tokyo (JP); Motoyuki SATO, Tokyo (JP); Kiyotaka IMAI, Tokyo (JP); Kumiko ONO, Tokyo (JP)

(21) Appl. No.: 19/671,400

(22) Filed: May 8, 2026

Related U.S. Application Data
(63) Continuation of application No. PCT/JP2024/039389, filed on Nov. 6, 2024.

(30) Foreign Application Priority Data
Nov. 16, 2023 (JP) 2023-194952

(51) Int. Cl. H10D 88/00; H10B 12/00; H10D 86/01; H10P 14/20; H10P 36/00; H10P 56/00

(52) U.S. Cl. CPC H10D 88/01; H10B 12/315; H10D 86/0214; H10P 14/3802; H10P 36/07; H10P 56/00

(57) ABSTRACT

A production method of a semiconductor device is provided and includes providing a silicon substrate including a first main surface; forming a silicon oxide film over the first main surface of the silicon substrate; forming an amorphous silicon film over the silicon oxide film; forming a metal layer over the amorphous silicon film; changing the amorphous silicon film into a crystal silicon film by annealing the silicon substrate over which the metal layer is formed; forming a transistor using a portion of the crystal silicon film as a channel; and forming a capacitor next to the transistor as viewed in a direction perpendicular to the first main surface, the capacitor being electrically connected to the transistor.

### CROSS-REFERENCE TO RELATED APPLICATIONS

This application is a continuation application of International Application No. PCT/JP2024/039389, filed on Nov. 6, 2024, and designated the U.S., which is based upon and claims priority to Japanese Patent Application No. 2023-194952, filed on Nov. 16, 2023, the entire contents of which are incorporated herein by reference.

### BACKGROUND

### Field of the Invention

The present disclosure relates to a production method of a semiconductor device.

### Description of the Related Art

A technique of sequentially forming an amorphous silicon film and a metal film over a substrate and performing annealing at a predetermined temperature to change the amorphous silicon film into a crystal silicon film, known (see, for example, Japanese Patent Application Publication Nos. 2006-303218 and 2002-313719).

### SUMMARY

A production method of a semiconductor device according to an aspect of the present disclosure includes: providing a silicon substrate including a first main surface; forming a silicon oxide film over the first main surface of the silicon substrate; forming an amorphous silicon film over the silicon oxide film; forming a metal layer over the amorphous silicon film; changing the amorphous silicon film into a crystal silicon film by annealing the silicon substrate over which the metal layer is formed; forming a transistor using a portion of the crystal silicon film as a channel; and forming a capacitor next to the transistor as viewed in a direction perpendicular to the first main surface, the capacitor being electrically connected to the transistor.

### BRIEF DESCRIPTION OF THE DRAWINGS

FIG. 1 is a cross-sectional diagram (part 1) illustrating a production method of a semiconductor device according to a first embodiment of the present disclosure.

FIG. 2 is a cross-sectional diagram (part 2) illustrating the production method of the semiconductor device according to the first embodiment.

FIG. 3 is a cross-sectional diagram (part 3) illustrating the production method of the semiconductor device according to the first embodiment.

FIG. 4 is a cross-sectional diagram (part 4) illustrating the production method of the semiconductor device according to the first embodiment.

FIG. 5 is a cross-sectional diagram (part 5) illustrating the production method of the semiconductor device according to the first embodiment.

FIG. 6 is a cross-sectional diagram (part 6) illustrating the production method of the semiconductor device according to the first embodiment.

FIG. 7 is a cross-sectional diagram (part 7) illustrating the production method of the semiconductor device according to the first embodiment.

FIG. 8 is a cross-sectional diagram (part 8) illustrating the production method of the semiconductor device according to the first embodiment.

FIG. 9 is a cross-sectional diagram (part 9) illustrating the production method of the semiconductor device according to the first embodiment.

FIG. 10 is a cross-sectional diagram (part 10) illustrating the production method of the semiconductor device according to the first embodiment.

FIG. 11 is a cross-sectional diagram (part 11) illustrating the production method of the semiconductor device according to the first embodiment.

FIG. 12 is a cross-sectional diagram (part 12) illustrating the production method of the semiconductor device according to the first embodiment.

FIG. 13 is a cross-sectional diagram (part 1) illustrating a production method of a semiconductor device according to a second embodiment of the present disclosure.

FIG. 14 is a cross-sectional diagram (part 2) illustrating the production method of the semiconductor device according to the second embodiment.

FIG. 15 is a cross-sectional diagram (part 3) illustrating the production method of the semiconductor device according to the second embodiment.

FIG. 16 is a cross-sectional diagram (part 4) illustrating the production method of the semiconductor device according to the second embodiment.

FIG. 17 is a cross-sectional diagram (part 5) illustrating the production method of the semiconductor device according to the second embodiment.

FIG. 18 is a cross-sectional diagram (part 6) illustrating the production method of the semiconductor device according to the second embodiment.

FIG. 19 is a cross-sectional diagram (part 7) illustrating the production method of the semiconductor device according to the second embodiment.

FIG. 20 is a cross-sectional diagram (part 8) illustrating the production method of the semiconductor device according to the second embodiment.

FIG. 21 is a cross-sectional diagram (part 9) illustrating the production method of the semiconductor device according to the second embodiment.

FIG. 22 is a cross-sectional diagram (part 10) illustrating the production method of the semiconductor device according to the second embodiment.

FIG. 23 is a cross-sectional diagram (part 11) illustrating the production method of the semiconductor device according to the second embodiment.

FIG. 24 is a cross-sectional diagram (part 1) illustrating a production method of a semiconductor device according to a third embodiment of the present disclosure.

FIG. 25 is a cross-sectional diagram (part 2) illustrating the production method of the semiconductor device according to the third embodiment.

FIG. 26 is a cross-sectional diagram (part 3) illustrating the production method of the semiconductor device according to the third embodiment.

FIG. 27 is a cross-sectional diagram (part 4) illustrating the production method of the semiconductor device according to the third embodiment.

FIG. 28 is a cross-sectional diagram (part 5) illustrating the production method of the semiconductor device according to the third embodiment.

FIG. 29 is a cross-sectional diagram (part 6) illustrating the production method of the semiconductor device according to the third embodiment.

FIG. 30 is a cross-sectional diagram (part 7) illustrating the production method of the semiconductor device according to the third embodiment.

FIG. 31 is a cross-sectional diagram (part 8) illustrating the production method of the semiconductor device according to the third embodiment.

FIG. 32 is a cross-sectional diagram (part 9) illustrating the production method of the semiconductor device according to the third embodiment.

FIG. 33 is a cross-sectional diagram (part 10) illustrating the production method of the semiconductor device according to the third embodiment.

FIG. 34 is a cross-sectional diagram (part 11) illustrating the production method of the semiconductor device according to the third embodiment.

FIG. 35 is a cross-sectional diagram (part 12) illustrating the production method of the semiconductor device according to the third embodiment.

FIG. 36 is a cross-sectional diagram (part 13) illustrating the production method of the semiconductor device according to the third embodiment.

### DETAILED DESCRIPTION OF THE DISCLOSURE

The present disclosure provides a technique of forming a semiconductor device including a transistor using a portion of a crystal silicon film as a channel, without using an SOI (Silicon On Insulator) substrate.

Hereinafter, non-limiting exemplary embodiments of the present disclosure will be described with reference to the drawings. In the drawings, the same or corresponding members or components are denoted by the same or corresponding reference signs, and thus duplicate descriptions thereof will be omitted.

### First Embodiment

A production method of a semiconductor device 1 according to a first embodiment of the present disclosure will be described with reference to FIGS. 1 to 12. FIGS. 1 to 12 are cross-sectional diagrams illustrating the production method of the semiconductor device 1 according to the first embodiment.

First, as illustrated in FIG. 1, a silicon substrate 112 is provided. The silicon substrate 112 includes a first main surface 112a and a second main surface 112b. The second main surface 112b is a surface opposite to the first main surface 112a. In the present embodiment, the silicon substrate 112 is a silicon single crystal substrate.

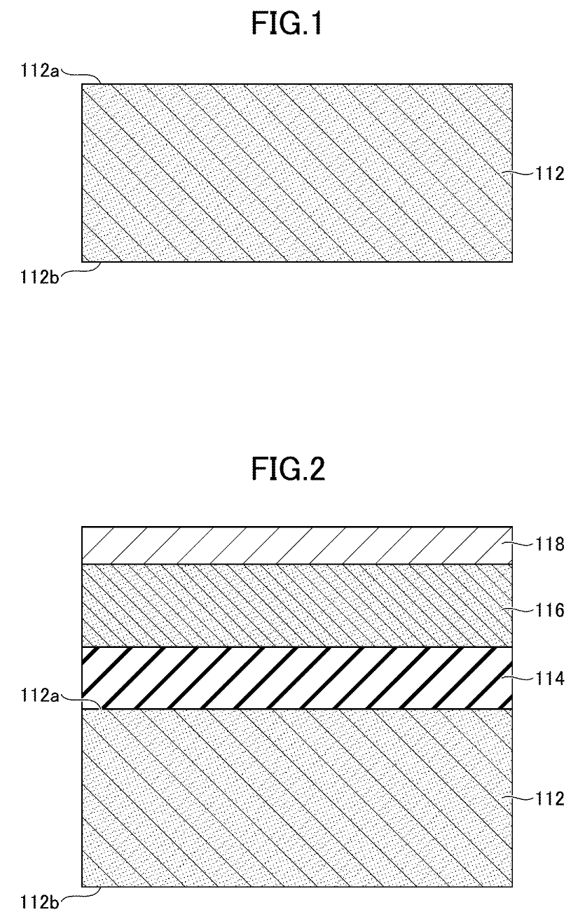

Next, as illustrated in FIG. 2, a silicon oxide film 114, an amorphous silicon film 116, and a metal layer 118 are sequentially formed over the first main surface 112a of the silicon substrate 112. In the present embodiment, first, the silicon oxide film 114 is formed over the first main surface 112a of the silicon substrate 112 through chemical vapor deposition (CVD), thermal oxidation, or the like. Next, the amorphous silicon film 116 is formed over the silicon oxide film 114 through CVD or the like. Next, the metal layer 118 is formed over the amorphous silicon film 116 through CVD, physical vapor deposition (PVD), or the like. The metal layer 118 is formed, for example, of nickel (Ni), a nickel-aluminum alloy (Ni-Al), cobalt (Co), or palladium (Pd). Next, alloying annealing may be performed, which silicidizes at least a portion of the metal layer 118 through reaction with silicon (Si), which forms the amorphous silicon film 116.

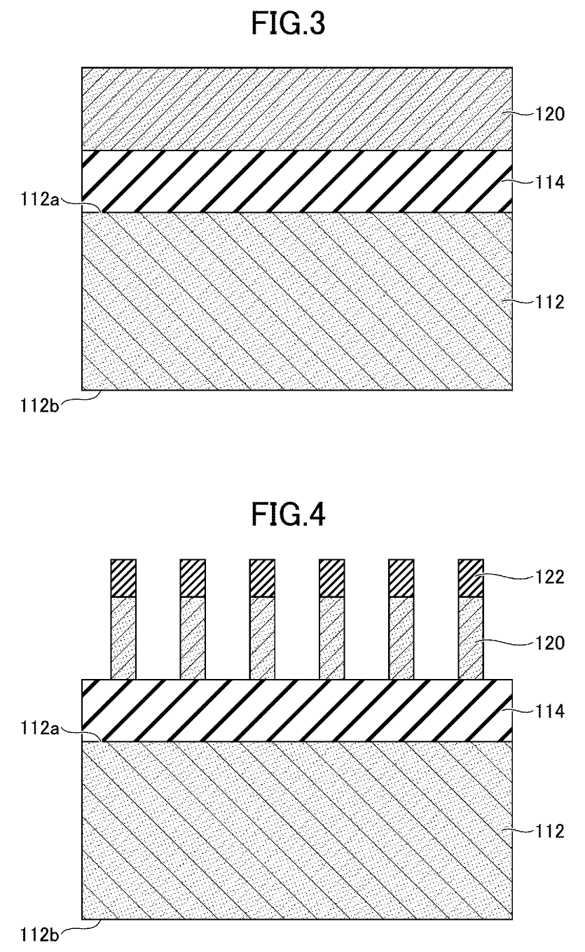

Next, as illustrated in FIG. 3, the amorphous silicon film 116 is changed into a crystal silicon film 120 by annealing the silicon substrate 112 over which the metal layer 118 is formed. In the present embodiment, the amorphous silicon film 116 is crystallized through metal-induced crystallization (MIC), metal-induced lateral crystallization (MILC), or the like, thereby forming the crystal silicon film 120. Specifically, the silicon substrate 112, over which the metal layer 118 is formed, is annealed at a predetermined temperature in an inert gas atmosphere. As a result, a metal forming the metal layer 118 diffuses into the amorphous silicon film 116, and the amorphous silicon film 116 is crystallized through metal-induced crystallization or metal-induced lateral crystallization using, as nuclei, the metal diffused into the amorphous silicon film 116, thereby forming the crystal silicon film 120. Here, the metal, forming the metal layer 118, can also diffuse into the silicon oxide film 114. Next, the metal layer 118 is removed through wet etching or the like.

Next, as illustrated in FIG. 4, the crystal silicon film 120 is processed into a columnar shape. In the present embodiment, first, a thin film for a hard mask 122 is formed over the crystal silicon film 120 through CVD or the like. The thin film for the hard mask 122 is, for example, an SiN film or an SiO₂ film. Next, a resist mask including an opening in a region other than a region where the crystal silicon film 120 is to be left is formed through lithography. Next, the crystal silicon film 120 is etched and removed using the resist mask. Next, the resist mask is removed. As a result, the crystal silicon film 120 is processed into a columnar shape extending in a direction perpendicular to the first main surface 112a.

Next, as illustrated in FIG. 5, a gate stack structure is formed. In the present embodiment, first, an insulating film 124 is formed over the silicon oxide film 114. The insulating film 124 is, for example, an SiN film, an SiOCN film, or an SiOC film. Next, an insulating film 126a for a gate insulating film 126 is formed over the side surface of the crystal silicon film 120 through thermal oxidation, atomic layer deposition (ALD), or the like. The insulating film 126a is, for example, an SiO₂ film or a High-k film. Next, a metal film 128a for a gate electrode 128 is formed to cover the crystal silicon film 120, the hard mask 122, the insulating film 124, and the insulating film 126a. The metal film 128a is formed, for example, of tungsten (W), cobalt, or molybdenum (Mo).

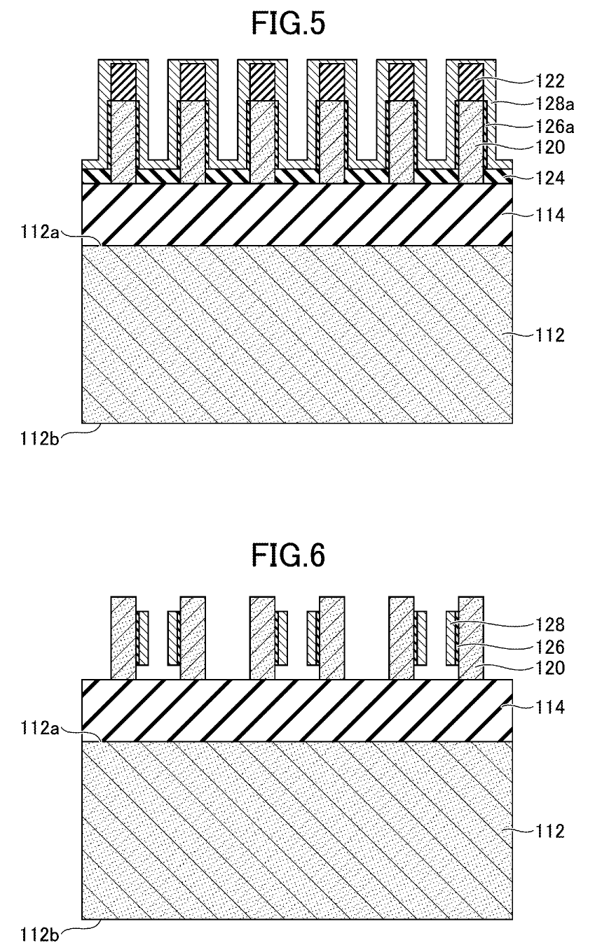

Next, as illustrated in FIG. 6, the gate insulating film 126 and the gate electrode 128 are formed. In the present embodiment, first, the insulating film 126a and the metal film 128a are etched through an etch-back process or the like, thereby leaving the insulating film 126a and the metal film 128a in a portion of the side surface of the crystal silicon film 120. Next, the hard mask 122 is etched and removed through wet etching, dry etching, or the like. Next, the insulating film 124 is etched and removed through wet etching, dry etching, or the like. As a result, the gate insulating film 126 is formed from the insulating film 126a, and the gate electrode 128 is formed from the metal film 128a. The gate insulating film 126 and the gate electrode 128 are formed, for example, in a center portion of the crystal silicon film 120 in the direction perpendicular to the first main surface 112a. The gate electrode 128 is electrically connected to a word line (not shown).

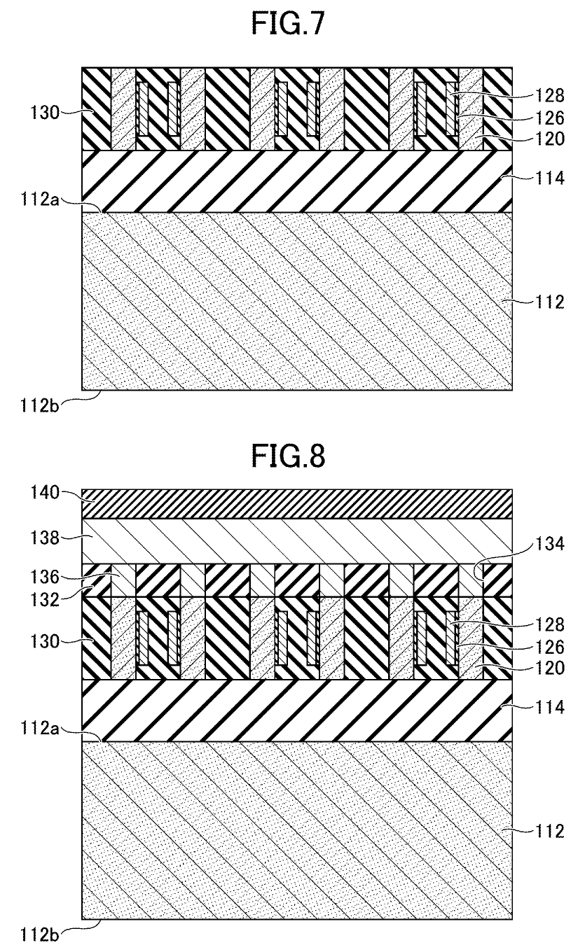

Next, as illustrated in FIG. 7, an interlayer insulating film 130 is formed. In the present embodiment, first, an insulating film for the interlayer insulating film 130 is formed to cover the silicon oxide film 114, the crystal silicon film 120, the gate insulating film 126, and the gate electrode 128. The insulating film for the interlayer insulating film 130 is, for example, an SiO₂ film, an SiOCN film, or an SiOC film. Next, the upper surface of the crystal silicon film 120 is exposed through chemical mechanical polishing (CMP) or the like. Thus, the interlayer insulating film 130 is formed. Next, ion implantation is performed on a bit line 138 side of the crystal silicon film 120. For example, through the ion implantation, a source region (not shown) is formed. In the ion implantation for forming the source region, n-type impurities, such as arsenic (As), phosphorus (P), or the like, are ion-implanted. The source region is electrically connected to the bit line 138. Next, activation annealing is performed through RTA (rapid thermal anneal), a heating furnace, or the like.

Next, as illustrated in FIG. 8, the bit line 138 is formed. In the present embodiment, first, an insulating film for the interlayer insulating film 132 is formed over the crystal silicon film 120 and the interlayer insulating film 130. The insulating film for the interlayer insulating film 132 is, for example, an SiO₂ film, an SiOCN film, or an SiOC film. Next, a resist mask including an opening is formed over the crystal silicon film 120 through lithography. Next, the insulating film for the interlayer insulating film 132 is etched and removed through dry etching or the like using the resist mask. This forms a via 134 from which the crystal silicon film 120 is exposed. Next, a metal film is formed such that the via 134 is embedded, and the surface is planarized through CMP or the like. As a result, a metal film 136 is formed in the via 134. The metal film 136 is formed, for example, of titanium nitride (TiN), tungsten, cobalt, molybdenum, or ruthenium (Ru). Next, an insulating film for an interlayer insulating film (not shown) for insulation between the bit lines 138 is formed over the interlayer insulating film 132 and the metal film 136. The insulating film for the interlayer insulating film is, for example, an SiO₂ film, an SiOCN film, or an SiOC film. Next, a resist mask including an opening in a region where the bit line 138 is to be formed is formed through lithography. Next, the insulating film for the interlayer insulating film is etched through dry etching or the like using the resist mask. This forms a trench from which the interlayer insulating film 132 and the metal film 136 are exposed. Next, a metal film for the bit line 138 is formed such that the trench is embedded, and the surface is planarized through CMP or the like. This forms the bit line 138 in the trench. The bit line 138 is formed of titanium nitride, tungsten, cobalt, molybdenum, or ruthenium. Next, an interlayer insulating film 140 is formed over the bit line 138 and the interlayer insulating film for insulation between the bit lines 138. The interlayer insulating film 140 is, for example, an SiO₂ film, an SiOCN film, or an SiOC film.

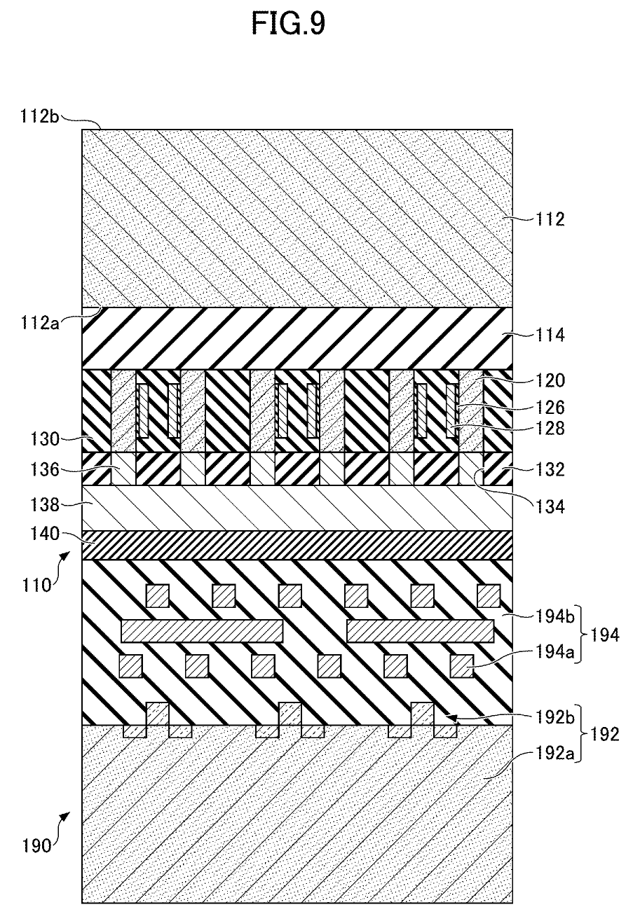

Next, as illustrated in FIG. 9, the first main surface 112a of the first substrate 110, over which up to the interlayer insulating film 140 is formed, is bonded to a second substrate 190 that is previously provided. In the present embodiment, the second substrate 190 is a CMOS (complementary metal oxide semiconductor) substrate. The second substrate 190 includes a CMOS portion 192 and an interconnect portion 194. The CMOS portion 192 includes a silicon substrate 192a and a plurality of transistors 192b. The plurality of transistors 192b include a P-type transistor and an N-type transistor. The interconnect portion 194 includes an interconnect 194a and an interlayer insulating film 194b. The interconnect 194a is formed into a multilayer structure. The interlayer insulating film 194b insulates between the interconnects 194a. The first substrate 110 and the second substrate 190 are bonded such that the interlayer insulating film 140 and the interconnect portion 194 contact each other.

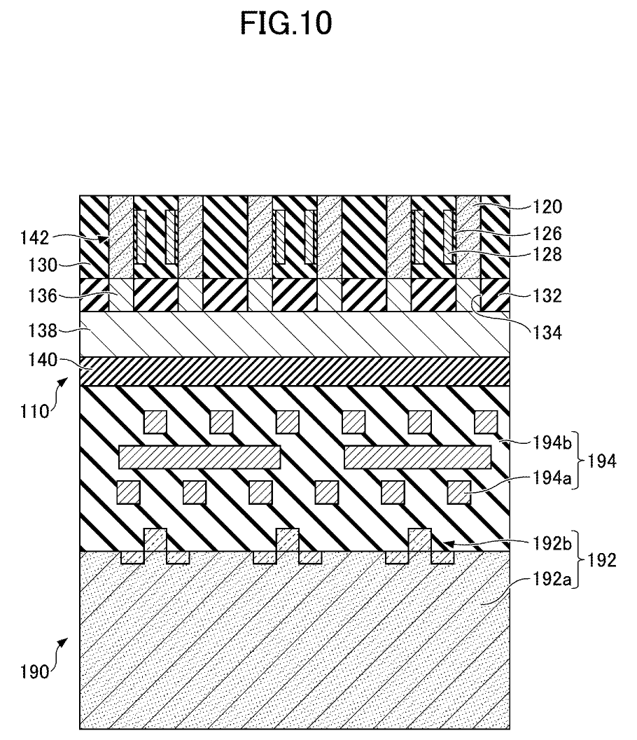

Next, as illustrated in FIG. 10, the silicon substrate 112 and the silicon oxide film 114 are removed from the second main surface 112b side of the silicon substrate 112, thereby thinning the first substrate 110. In the present embodiment, first, grinding and CMP are sequentially performed to polish the silicon substrate 112 from the second main surface 112b side. Next, the silicon substrate 112 is selectively etched and removed from the silicon oxide film 114 through wet etching, dry etching, or the like. Instead of grinding, the silicon substrate 112 may be removed through laser lift-off or a separation technique using a laser. In the case of using the laser lift-off, for example, a separation layer is provided between the silicon substrate 112 and the silicon oxide film 114, and then the separation layer is separated through laser irradiation, thereby removing the silicon substrate 112 along with the separation layer. In the case of using the separation technique using a laser, for example, a modified layer is formed inside the silicon substrate 112 through laser irradiation, and then the silicon substrate 112 can be removed starting from the modified layer. Next, the silicon oxide film 114 is selectively etched and removed from the crystal silicon film 120 and the interlayer insulating film 130. In this case, a metal, which can diffuse into the silicon oxide film 114, is removed along with the silicon oxide film 114, and thus is not left in the semiconductor device 1, which is a final product. Also, it is easy to make uniform the length of the columnar crystal silicon film 120, which does not overlap with the gate electrode 128, over the entire surface of the first substrate 110. When the length of the crystal silicon film 120 is controlled by stopping the etching before completion instead of using the etching selectivity, it is difficult to make uniform the length of the columnar crystal silicon film 120, which does not overlap with the gate electrode 128, over the entire surface of the first substrate 110. Next, ion implantation is performed on a capacitor 160 side of the crystal silicon film 120. For example, a drain region (not shown) is formed through the ion implantation. This forms a transistor 142 including a channel (not shown) between the source region and the drain region of the crystal silicon film 120. In the ion implantation for forming the drain region, n-type impurities, such as arsenic, phosphorus, or the like, are ion-implanted. The drain region is electrically connected to the capacitor 160. Next, activation annealing is performed through RTA, a heating furnace, or the like.

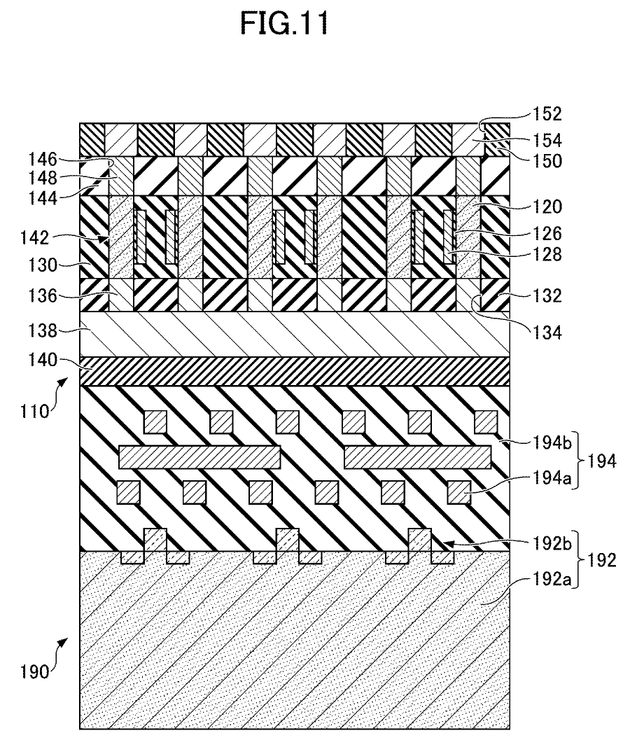

Next, as illustrated in FIG. 11, a pad 154 for the capacitor 160 is formed. In the present embodiment, first, an insulating film for the interlayer insulating film 144 is formed over the crystal silicon film 120 and the interlayer insulating film 130. The insulating film for the interlayer insulating film 144 is, for example, an SiO₂ film, an SiOCN film, or an SiOC film. Next, a resist mask including an opening is formed over the crystal silicon film 120 through lithography. Next, the insulating film for the interlayer insulating film 144 is etched and removed through dry etching or the like using the resist mask. This forms a via 146 from which the crystal silicon film 120 is exposed. Next, a metal film is formed such that the via 146 is embedded, and the surface is planarized through CMP or the like. This forms a metal film 148 inside the via 146. The metal film 148 is formed, for example, of titanium nitride, tungsten, cobalt, molybdenum, or ruthenium. Next, an insulating film for an interlayer insulating film 150 is formed over the interlayer insulating film 144 and the metal film 148. The insulating film for the interlayer insulating film 150 is, for example, an SiO₂ film, an SiOCN film, or an SiOC film. Next, a resist mask including an opening is formed over the metal film 148 through lithography. Next, the insulating film for the interlayer insulating film 150 is etched and removed through dry etching or the like using the resist mask. This forms an opening 152 from which the metal film 148 is exposed. Next, a metal film is formed such that the opening 152 is embedded, and the surface is planarized through CMP or the like. This forms the pad 154 inside the opening 152. The pad 154 is formed, for example, of titanium nitride, tungsten, cobalt, molybdenum, or ruthenium.

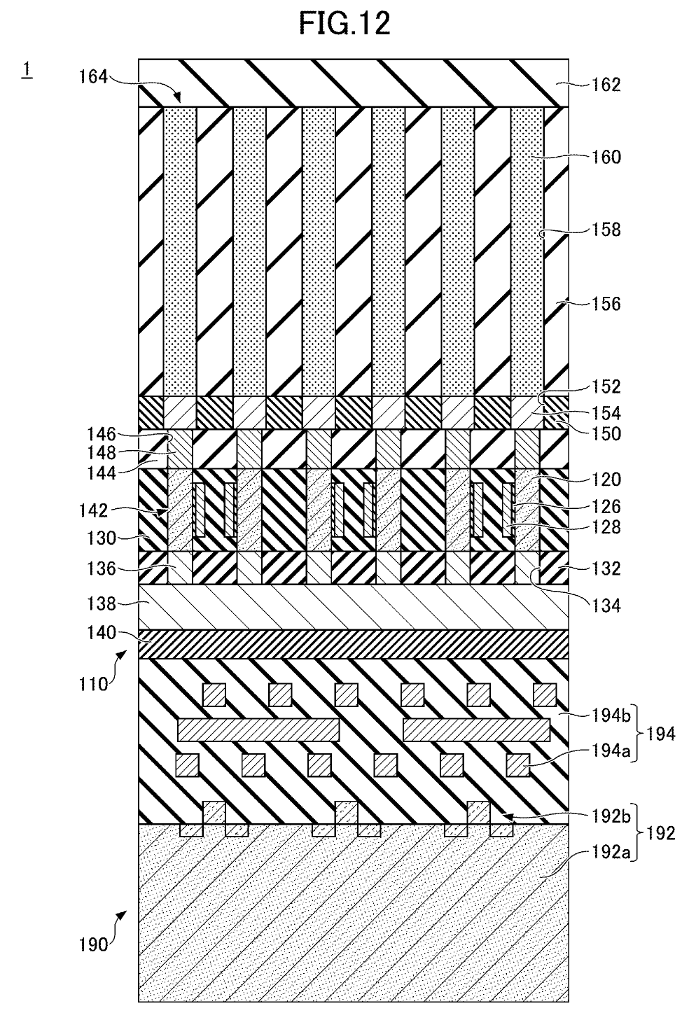

Next, as illustrated in FIG. 12, the capacitor 160 is formed next to the transistor 142 as viewed in the direction perpendicular to the first main surface 112a, the capacitor 160 being electrically connected to the transistor 142. In the present embodiment, first, an insulating film for an interlayer insulating film 156 is formed over the interlayer insulating film 150 and the pad 154. The insulating film for the interlayer insulating film 156 is, for example, an SiO₂ film, an SiOCN film, or an SiOC film. Next, a resist mask including an opening is formed over the pad 154 through lithography. Next, the insulating film for the interlayer insulating film 156 is etched and removed through dry etching or the like using the resist mask. This forms a capacitor hole 158 from which the pad 154 is exposed. Next, the capacitor 160 is formed inside the capacitor hole 158. The capacitor 160 has, for example, a structure in which an insulating film is sandwiched between metal films. Next, an insulating film 162 covering the upper surface of the interlayer insulating film 156 and the upper surface of the capacitor 160 is formed.

Through the above process, the semiconductor device 1 according to the first embodiment is produced. The semiconductor device 1 is configured as a DRAM (dynamic random access memory) including a plurality of memory cells 164. Each memory cell 164 includes the transistor 142 and the capacitor 160 that are connected in series.

As described above, according to the production method of the semiconductor device 1 according to the first embodiment, first, the silicon substrate 112 including the first main surface 112a is provided. Next, the silicon oxide film 114, the amorphous silicon film 116, and the metal layer 118 are sequentially formed over the first main surface 112a of the silicon substrate 112. Next, the amorphous silicon film 116 is changed into the crystal silicon film 120 by annealing the silicon substrate 112 over which the metal layer 118 is formed. Next, the transistor 142 using a portion of the crystal silicon film 120 as a channel is formed. Next, the capacitor 160 is formed that is next to the transistor 142 in the direction perpendicular to the first main surface 112a, and is electrically connected to the transistor 142. In this case, the semiconductor device 1 including the transistor 142 using a portion of the crystal silicon film 120 as a channel can be formed without using an SOI substrate.

### Second Embodiment

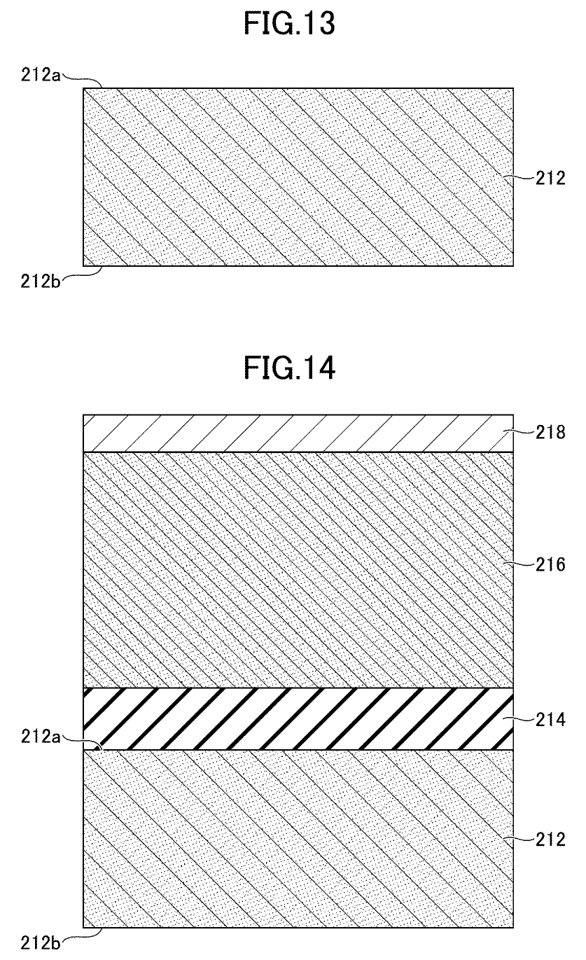

A production method of a semiconductor device 2 according to a second embodiment of the present disclosure will be described with reference to FIGS. 13 to 23. FIGS. 13 to 23 are cross-sectional diagrams illustrating the production method of the semiconductor device 2 according to the second embodiment.

First, as illustrated in FIG. 13, a silicon substrate 212 is provided. The silicon substrate 212 includes a first main surface 212a and a second main surface 212b. The second main surface 212b is a surface opposite to the first main surface 212a. In the present embodiment, the silicon substrate 212 is a silicon single crystal substrate.

Next, as illustrated in FIG. 14, a silicon oxide film 214, an amorphous silicon film 216, and a metal layer 218 are sequentially formed over the first main surface 212a of the silicon substrate 212. In the present embodiment, first, the silicon oxide film 214 is formed over the first main surface 212a of the silicon substrate 212 through CVD, thermal oxidation, or the like. Next, the amorphous silicon film 216 is formed over the silicon oxide film 214 through CVD or the like. The amorphous silicon film 216 is deposited to have a film thickness larger than that of the crystal silicon film 220 left in the semiconductor device 2, which is a final product. For example, the film thickness of the amorphous silicon film 216 may be twice or more of the film thickness of the crystal silicon film 220 left in the final semiconductor device 2. Next, the metal layer 218 is formed over the amorphous silicon film 216 through CVD, PVD, or the like. The metal layer 218 can be formed in the same manner as in the metal layer 118.

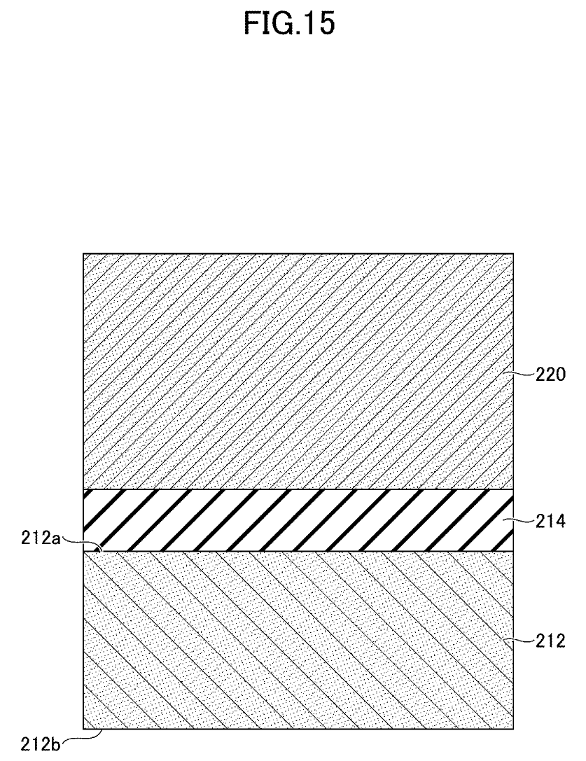

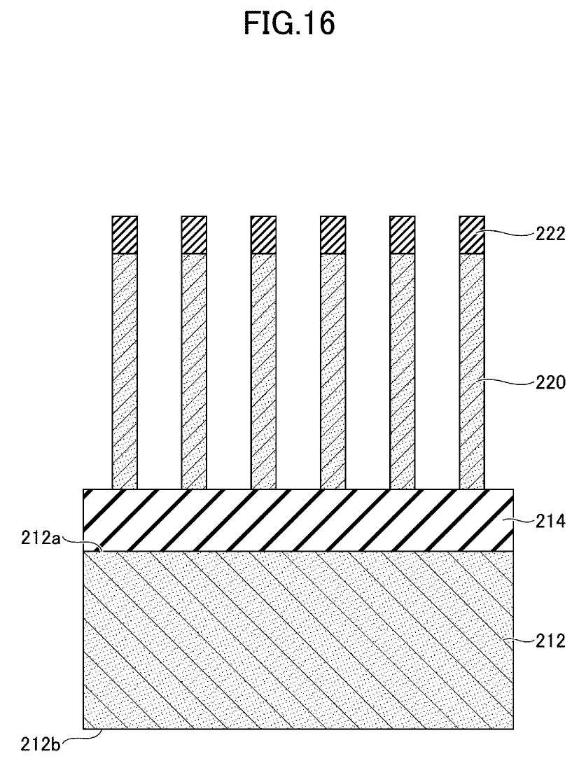

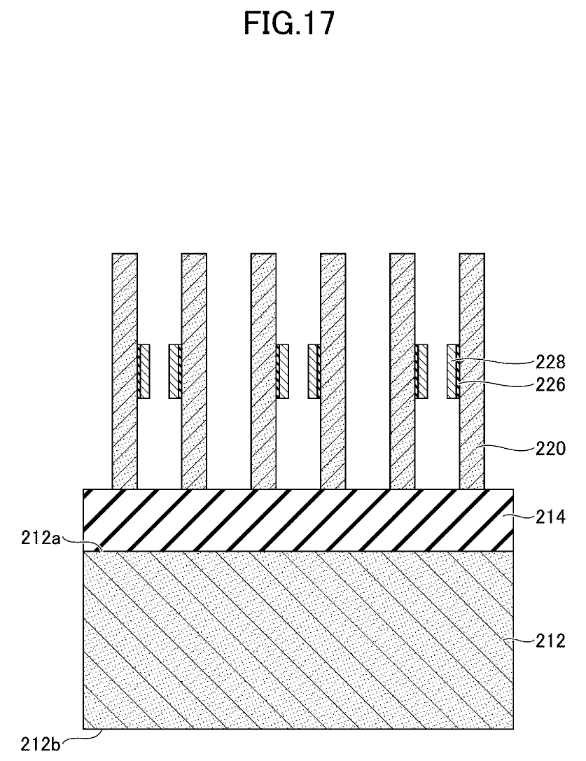

Next, as illustrated in FIG. 15, the amorphous silicon film 216 is changed into a crystal silicon film 220 by annealing the silicon substrate 212 over which the metal layer 218 is formed. The crystal silicon film 220 can be formed in the same manner as in the crystal silicon film 120.

Next, as illustrated in FIG. 16, the crystal silicon film 220 is processed into a columnar shape. In the present embodiment, first, a thin film for a hard mask 222 is formed over the crystal silicon film 220 through CVD or the like. The thin film for the hard mask 222 is, for example, an SiN film or an SiO₂ film. Next, a resist mask including an opening in a region other than a region where the crystal silicon film 220 is to be left is formed through lithography. Next, the crystal silicon film 220 is etched and removed using the resist mask. Next, the resist mask is removed. As a result, the crystal silicon film 220 is processed into a columnar shape extending in a direction perpendicular to the first main surface 212a.

Next, as illustrated in FIG. 17, a gate insulating film 226 and a gate electrode 228 are formed. The gate insulating film 226 and the gate electrode 228 can be respectively formed in the same manner as in the gate insulating film 126 and the gate electrode 128. The gate insulating film 226 and the gate electrode 228 are formed, for example, in a center portion of the crystal silicon film 220 in the direction perpendicular to the first main surface 212a.

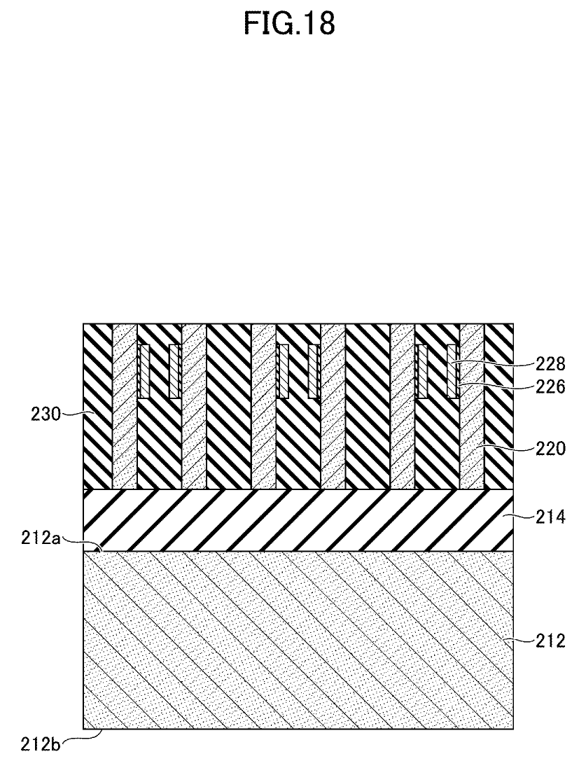

Next, as illustrated in FIG. 18, an interlayer insulating film 230 is formed. In the present embodiment, first, an insulating film for the interlayer insulating film 230 is formed to cover the silicon oxide film 214, the crystal silicon film 220, the gate insulating film 226, and the gate electrode 228. The insulating film for the interlayer insulating film 230 is, for example, an SiO₂ film, an SiOCN film, or an SiOC film. Next, the upper surface of the crystal silicon film 220 is exposed through CMP or the like. Thus, the interlayer insulating film 230 is formed. Here, the crystal silicon film 220 is polished up to the vicinity of the gate electrode 228, thereby reducing the film thickness. In this case, a region in the vicinity of a starting point of metal-induced crystallization or metal-induced lateral crystallization is removed from the crystal silicon film 220. In the region in the vicinity of the starting point of metal-induced crystallization or metal-induced lateral crystallization, crystallinity tends to deteriorate or crystallinity tends to be non-uniform. Therefore, by removing the region in the vicinity of the starting point of metal-induced crystallization or metal-induced lateral crystallization, the crystal silicon film 220 with good crystallinity can be used as a channel. Next, ion implantation is performed on a bit line 238 side of the crystal silicon film 220. For example, through the ion implantation, a source region (not shown) is formed. In the ion implantation for forming the source region, n-type impurities, such as arsenic, phosphorus, or the like, are ion-implanted. The source region is electrically connected to the bit line 238. Next, activation annealing is performed through RTA, a heating furnace, or the like.

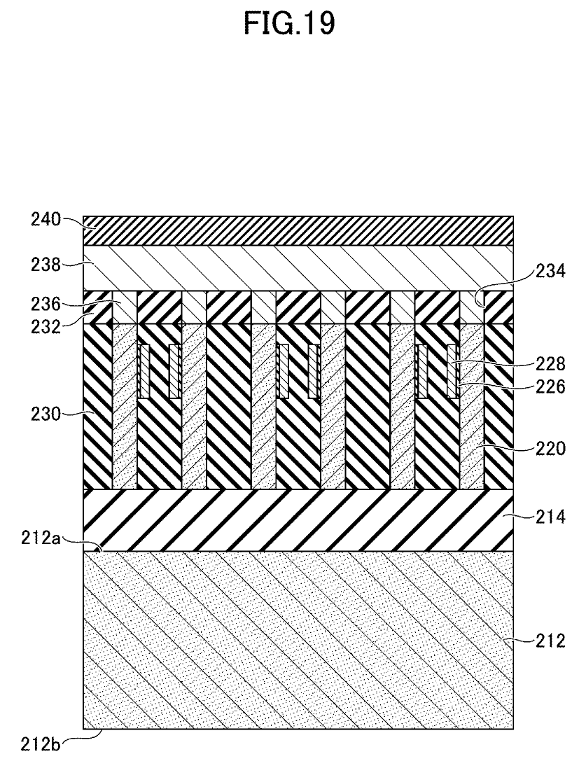

Next, as illustrated in FIG. 19, the bit line 238 is formed. In the present embodiment, first, an insulating film for the interlayer insulating film 232 is formed over the crystal silicon film 220 and the interlayer insulating film 230. The insulating film for the interlayer insulating film 232 is, for example, an SiO₂ film, an SiOCN film, or an SiOC film. Next, a resist mask including an opening is formed over the crystal silicon film 220 through lithography. Next, the insulating film for the interlayer insulating film 232 is etched and removed through dry etching or the like using the resist mask. This forms a via 234 from which the crystal silicon film 220 is exposed. Next, a metal film is formed such that the via 234 is embedded, and the surface is planarized through CMP or the like. As a result, a metal film 236 is formed in the via 234. The metal film 236 is formed, for example, of titanium nitride, tungsten, cobalt, molybdenum, or ruthenium. Next, an insulating film for an interlayer insulating film (not shown) for insulation between the bit lines 238 is formed over the interlayer insulating film 232 and the metal film 236. The insulating film for the interlayer insulating film is, for example, an SiO₂ film, an SiOCN film, or an SiOC film. Next, a resist mask including an opening in a region where the bit line 238 is to be formed is formed through lithography. Next, the insulating film for the interlayer insulating film is etched through dry etching or the like using the resist mask. This forms a trench from which the interlayer insulating film 232 and the metal film 236 are exposed. Next, a metal film for the bit line 238 is formed such that the trench is embedded, and the surface is planarized through CMP or the like. This forms the bit line 238 in the trench. The bit line 238 is formed of titanium nitride, tungsten, cobalt, molybdenum, or ruthenium. Next, an interlayer insulating film 240 is formed over the bit line 238 and the interlayer insulating film for insulation between the bit lines 238. The interlayer insulating film 240 is, for example, an SiO₂ film, an SiOCN film, or an SiOC film.

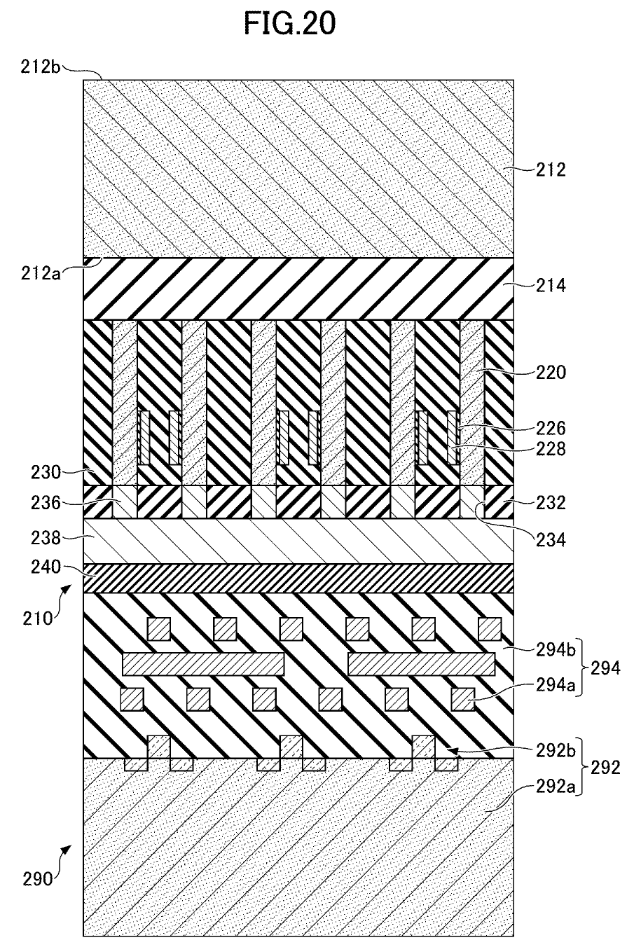

Next, as illustrated in FIG. 20, the first main surface 212a of the first substrate 210, over which up to the interlayer insulating film 240 is formed, is bonded to a second substrate 290 that is previously provided. In the present embodiment, the second substrate 290 is a CMOS substrate. The second substrate 290 includes a CMOS portion 292 and an interconnect portion 294. The CMOS portion 292 includes a silicon substrate 292a and a plurality of transistors 292b. The plurality of transistors 292b include a P-type transistor and an N-type transistor. The interconnect portion 294 includes an interconnect 294a and an interlayer insulating film 294b. The interconnect 294a is formed into a multilayer structure. The interlayer insulating film 294b insulates between the interconnects 294a. The first substrate 210 and the second substrate 290 are bonded such that the interlayer insulating film 240 and the interconnect portion 294 contact each other.

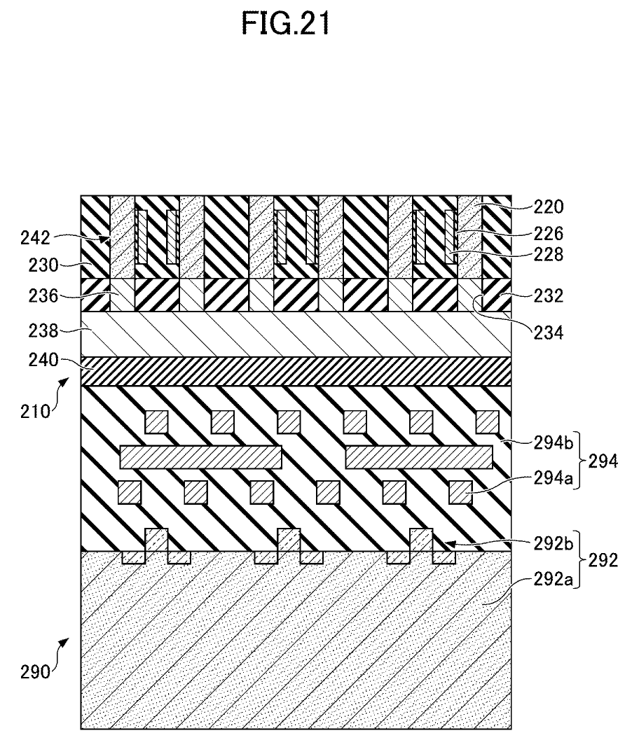

Next, as illustrated in FIG. 21, the silicon substrate 212, the silicon oxide film 214, a portion of the crystal silicon film 220, and a portion of the interlayer insulating film 230 are removed from the second main surface 212b side of the silicon substrate 212, thereby thinning the first substrate 210. In the present embodiment, first, grinding and CMP are sequentially performed to polish and remove the silicon substrate 212, the silicon oxide film 214, the portion of the crystal silicon film 220, and the portion of the interlayer insulating film 230 from the second main surface 212b side. In this case, a metal, which can diffuse into the silicon oxide film 214, is removed along with the silicon oxide film 214, and thus is not left in the semiconductor device 2, which is a final product. In the case of polishing the portion of the crystal silicon film 220, the crystal silicon film 220 is polished up to the vicinity of the gate electrode 228 to reduce the film thickness of the crystal silicon film 220. In this case, a region in the vicinity of the end point of metal-induced crystallization or metal-induced lateral crystallization is removed from the crystal silicon film 220. In the region in the vicinity of the end point of metal-induced crystallization or metal-induced lateral crystallization, crystallinity tends to deteriorate or crystallinity tends to be non-uniform. Therefore, by removing the region in the vicinity of the end point of metal-induced crystallization or metal-induced lateral crystallization, the crystal silicon film 220 with good crystallinity can be used as a channel. Next, ion implantation is performed on a capacitor 260 side of the crystal silicon film 220. For example, a drain region (not shown) is formed through the ion implantation. This forms a transistor 242 including a channel (not shown) between the source region and the drain region of the crystal silicon film 220. In the ion implantation for forming the drain region, n-type impurities, such as arsenic, phosphorus, or the like, are ion-implanted. The drain region is electrically connected to the capacitor 260. Next, activation annealing is performed through RTA, a heating furnace, or the like.

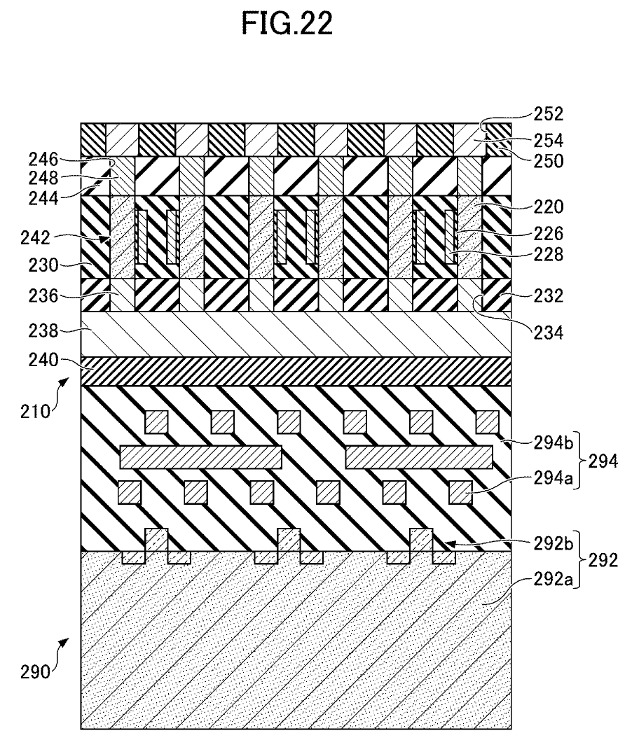

Next, as illustrated in FIG. 22, a pad 254 for the capacitor 260 is formed. In the present embodiment, first, an insulating film for the interlayer insulating film 244 is formed over the crystal silicon film 220 and the interlayer insulating film 230. The insulating film for the interlayer insulating film 244 is, for example, an SiO₂ film, an SiOCN film, or an SiOC film. Next, a resist mask including an opening is formed over the crystal silicon film 220 through lithography. Next, the insulating film for the interlayer insulating film 244 is etched and removed through dry etching or the like using the resist mask. This forms a via 246 from which the crystal silicon film 220 is exposed. Next, a metal film is formed such that the via 246 is embedded, and the surface is planarized through CMP or the like. This forms a metal film 248 inside the via 246. The metal film 248 is formed, for example, of titanium nitride, tungsten, cobalt, molybdenum, or ruthenium. Next, an insulating film for an interlayer insulating film 250 is formed over the interlayer insulating film 244 and the metal film 248. The insulating film for the interlayer insulating film 250 is, for example, an SiO₂ film, an SiOCN film, or an SiOC film. Next, a resist mask including an opening is formed over the metal film 248 through lithography. Next, the insulating film for the interlayer insulating film 250 is etched and removed through dry etching or the like using the resist mask. This forms an opening 252 from which the metal film 248 is exposed. Next, a metal film is formed such that the opening 252 is embedded, and the surface is planarized through CMP or the like. This forms the pad 254 inside the opening 252. The pad 254 is formed, for example, of titanium nitride, tungsten, cobalt, molybdenum, or ruthenium.

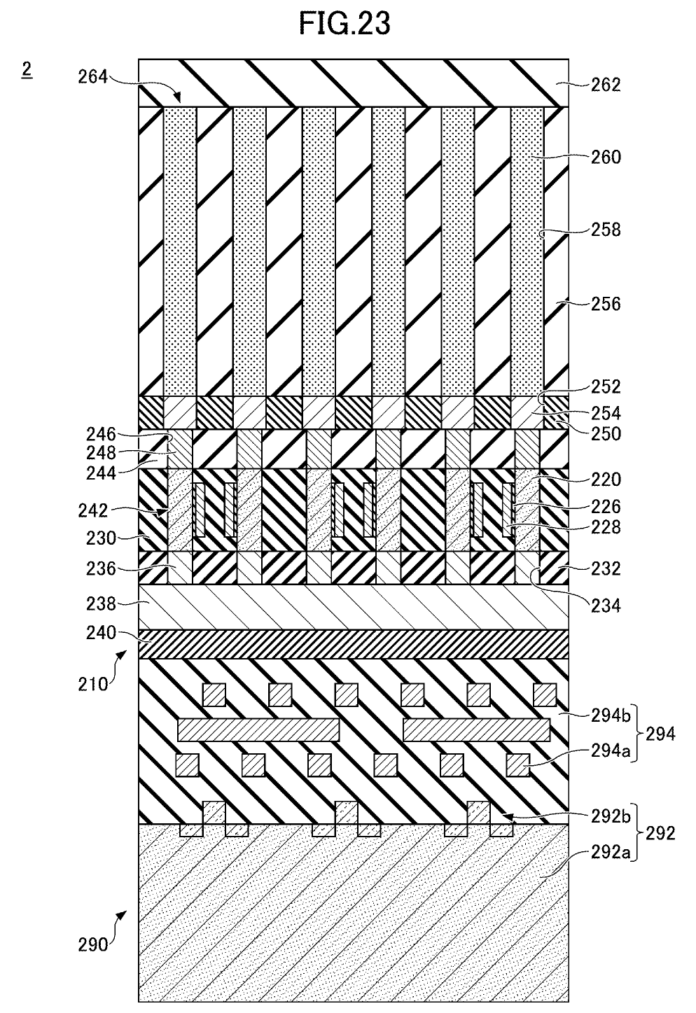

Next, as illustrated in FIG. 23, the capacitor 260 is formed that is next to the transistor 242 in the direction perpendicular to the first main surface 212a, and is electrically connected to the transistor 242. In the present embodiment, first, an insulating film for an interlayer insulating film 256 is formed over the interlayer insulating film 250 and the pad 254. The insulating film for the interlayer insulating film 256 is, for example, an SiO₂ film, an SiOCN film, or an SiOC film. Next, a resist mask including an opening is formed over the pad 254 through lithography. Next, the insulating film for the interlayer insulating film 256 is etched and removed through dry etching or the like using the resist mask. This forms a capacitor hole 258 from which the pad 254 is exposed. Next, the capacitor 260 is formed inside the capacitor hole 258. The capacitor 260 has, for example, a structure in which an insulating film is sandwiched between metal films. Next, an insulating film 262 covering the upper surface of the interlayer insulating film 256 and the upper surface of the capacitor 260 is formed.

Through the above process, the semiconductor device 2 according to the second embodiment is produced. The semiconductor device 2 is configured as a DRAM including a plurality of memory cells 264. Each memory cell 264 includes the transistor 242 and the capacitor 260 that are connected in series.

As described above, according to the production method of the semiconductor device 2 according to the second embodiment, first, the silicon substrate 212 including the first main surface 212a is provided. Next, the silicon oxide film 214, the amorphous silicon film 216, and the metal layer 218 are sequentially formed over the first main surface 212a of the silicon substrate 212. Next, the amorphous silicon film 216 is changed into the crystal silicon film 220 by annealing the silicon substrate 212 over which the metal layer 218 is formed. Next, the transistor 242 using a portion of the crystal silicon film 220 as a channel is formed. Next, the capacitor 260 is formed that is next to the transistor 242 in the direction perpendicular to the first main surface 212a, and is electrically connected to the transistor 242. In this case, the semiconductor device 2 including the transistor 242 using a portion of the crystal silicon film 220 as a channel can be formed without using an SOI substrate.

According to the production method of the semiconductor device 2 according to the second embodiment, the region in the vicinity of the starting point of metal-induced crystallization or metal-induced lateral crystallization and the region in the vicinity of the end point of metal-induced crystallization or metal-induced lateral crystallization are removed from the crystal silicon film 220. In this case, the crystal silicon film 220 with good crystallinity can be used as a channel.

### Third Embodiment

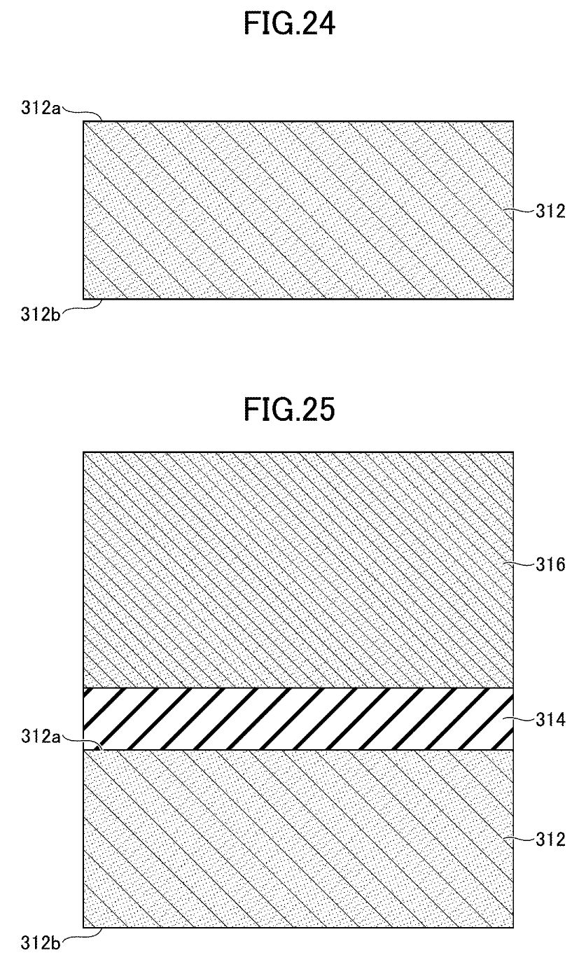

A production method of a semiconductor device 3 according to a third embodiment of the present disclosure will be described with reference to FIGS. 24 to 36. FIGS. 24 to 36 are cross-sectional diagrams illustrating the production method of the semiconductor device 3 according to the third embodiment.

First, as illustrated in FIG. 24, a silicon substrate 312 is provided. The silicon substrate 312 includes a first main surface 312a and a second main surface 312b. The second main surface 312b is a surface opposite to the first main surface 312a. In the present embodiment, the silicon substrate 312 is a silicon single crystal substrate.

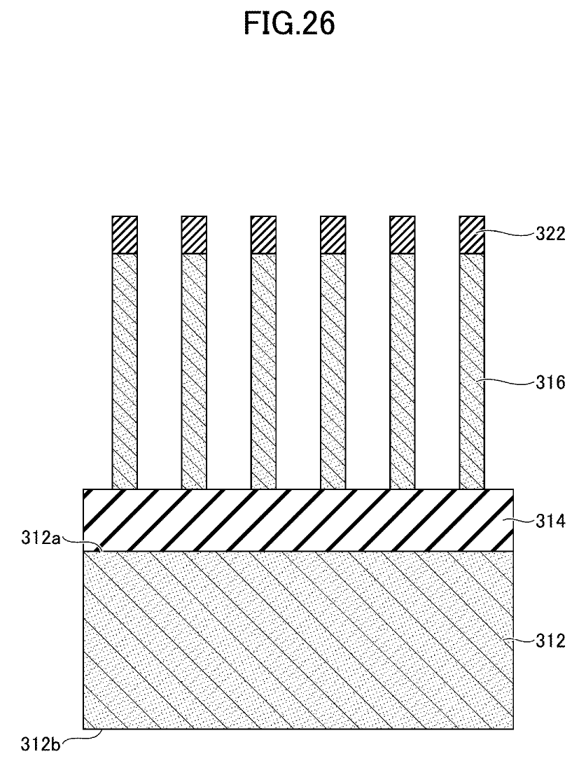

Next, as illustrated in FIG. 25, a silicon oxide film 314 and an amorphous silicon film 316 are sequentially formed over the first main surface 312a of the silicon substrate 312. In the present embodiment, first, the silicon oxide film 314 is formed over the first main surface 312a of the silicon substrate 312 through CVD, thermal oxidation, or the like. Next, the amorphous silicon film 316 is formed over the silicon oxide film 314 through CVD or the like. For example, the amorphous silicon film 316 is deposited to have a film thickness the same as that of the amorphous silicon film 216.

Next, as illustrated in FIG. 26, the amorphous silicon film 316 is processed into a columnar shape. In the present embodiment, first, a thin film for a hard mask 322 is formed over the amorphous silicon film 316 through CVD or the like. The thin film for the hard mask 322 is, for example, an SiN film or an SiO₂ film. Next, a resist mask including an opening in a region other than a region where the amorphous silicon film 316 is to be left is formed through lithography. Next, the amorphous silicon film 316 is etched and removed using the resist mask. Next, the resist mask is removed. As a result, the amorphous silicon film 316 is processed into a columnar shape extending in a direction perpendicular to the first main surface 312a.

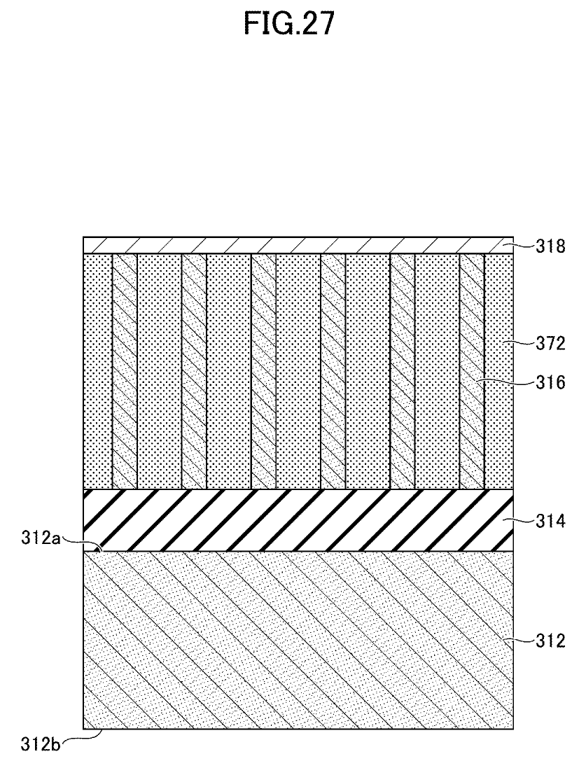

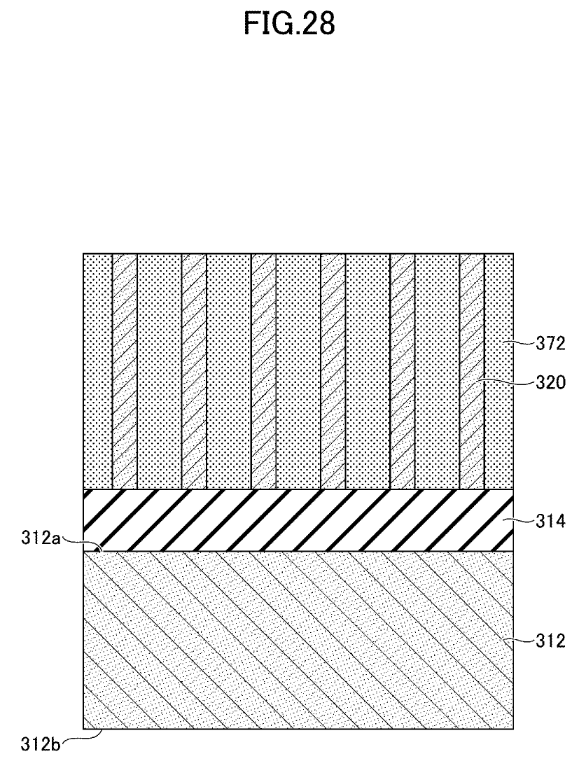

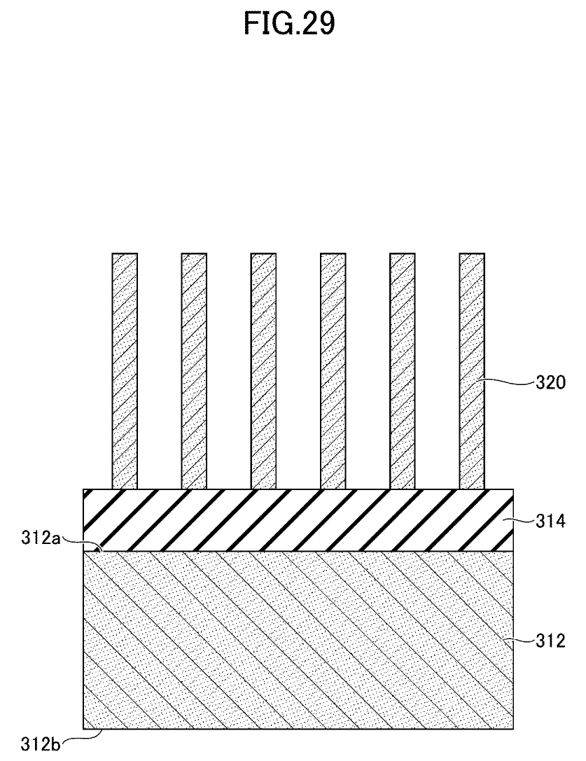

Next, as illustrated in FIG. 27, a gettering film 372 and a metal layer 318 are formed. In the present embodiment, first, the hard mask 322 is etched and removed through wet etching, dry etching, or the like. Next, a thin film for the gettering film 372 is formed to cover side and upper surfaces of the amorphous silicon film 316. The thin film for the gettering film 372 is, for example, an SiO₂ film, an SiN film, or a polysilicon film doped with impurities. Next, the upper surface of the amorphous silicon film 316 is exposed through CMP or the like. This forms the gettering film 372. Next, the metal layer 318 is formed over the amorphous silicon film 316 and the gettering film 372 through CVD, PVD, or the like. The metal layer 318 can be formed in the same manner as in the metal layer 118.

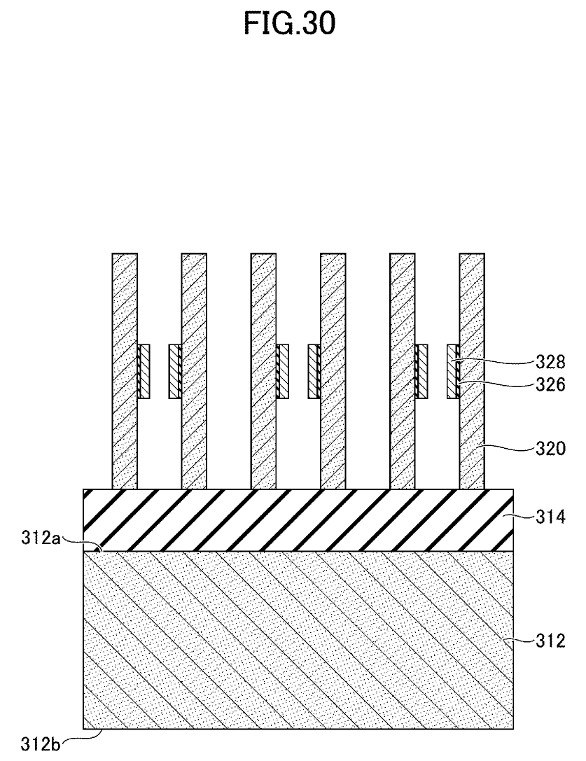

Next, as illustrated in FIG. 28, the amorphous silicon film 316 is changed into a crystal silicon film 320 by annealing the silicon substrate 312 over which the metal layer 318 is formed. In the present embodiment, the amorphous silicon film 316 is crystallized through metal-induced crystallization, metal-induced lateral crystallization, or the like, thereby forming the crystal silicon film 320. Specifically, the silicon substrate 312, over which the metal layer 318 is formed, is annealed at a predetermined temperature in an inert gas atmosphere. As a result, a metal forming the metal layer 318 diffuses into the amorphous silicon film 316, and the amorphous silicon film 316 is crystallized through metal-induced crystallization or metal-induced lateral crystallization using the metal diffused into the amorphous silicon film 316 as nuclei, thereby forming the crystal silicon film 320. Here, the metal forming the metal layer 318 can be left in the crystal silicon film 320. The concentration of the metal left in the crystal silicon film 320 can be reduced by diffusing the residual metal from the crystal silicon film 320 into the silicon oxide film 314 and the gettering film 372 through annealing. As a result, it is possible to improve reliability of the transistor 342 using the crystal silicon film 320 as a channel. Next, the metal layer 318 is removed through wet etching or the like.

Next, as illustrated in FIG. 29, the gettering film 372 is etched and removed through dry etching, wet etching, or the like. This can prevent the metal in the gettering film 372 being taken into the crystal silicon film 320 again.

Next, as illustrated in FIG. 30, a gate insulating film 326 and a gate electrode 328 are formed. The gate insulating film 326 and the gate electrode 328 can be respectively formed in the same manner as in the gate insulating film 126 and the gate electrode 128. The gate insulating film 326 and the gate electrode 328 are formed, for example, in a center portion of the crystal silicon film 320 in the direction perpendicular to the first main surface 312a.

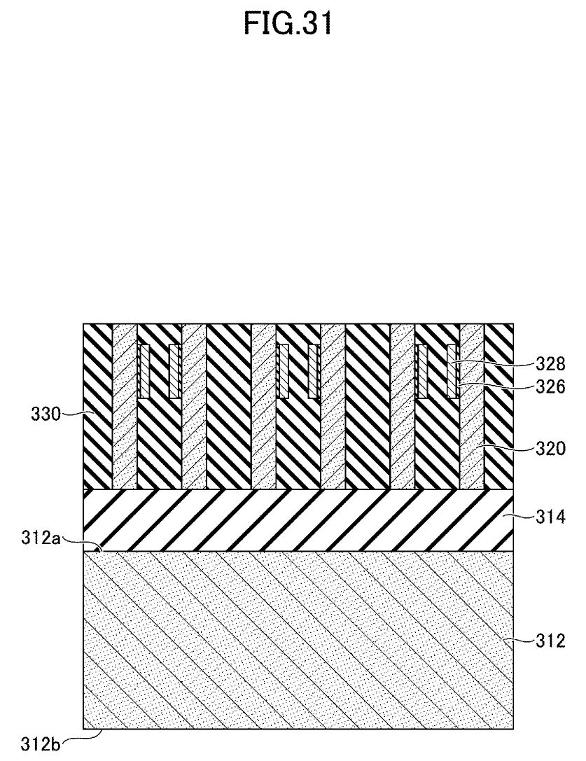

Next, as illustrated in FIG. 31, an interlayer insulating film 330 is formed. In the present embodiment, first, an insulating film for the interlayer insulating film 330 is formed to cover the silicon oxide film 314, the crystal silicon film 320, the gate insulating film 326, and the gate electrode 328. The insulating film for the interlayer insulating film 330 is, for example, an SiO₂ film, an SiOCN film, or an SiOC film. Next, the upper surface of the crystal silicon film 320 is exposed through CMP or the like. Thus, the interlayer insulating film 330 is formed. Here, the crystal silicon film 320 is polished up to the vicinity of the gate electrode 328, thereby reducing the film thickness. In this case, a region in the vicinity of a starting point of metal-induced crystallization or metal-induced lateral crystallization in the crystal silicon film 320 is removed. In the region in the vicinity of the starting point of metal-induced crystallization or metal-induced lateral crystallization, crystallinity tends to deteriorate or crystallinity tends to be non-uniform. Therefore, by removing the region in the vicinity of the starting point of metal-induced crystallization or metal-induced lateral crystallization, the crystal silicon film 320 with good crystallinity can be used as a channel. Next, ion implantation is performed on a bit line 338 side of the crystal silicon film 320. For example, through the ion implantation, a source region (not shown) is formed. In the ion implantation for forming the source region, n-type impurities, such as arsenic, phosphorus, or the like, are ion-implanted. The source region is electrically connected to the bit line 338. Next, activation annealing is performed through RTA, a heating furnace, or the like.

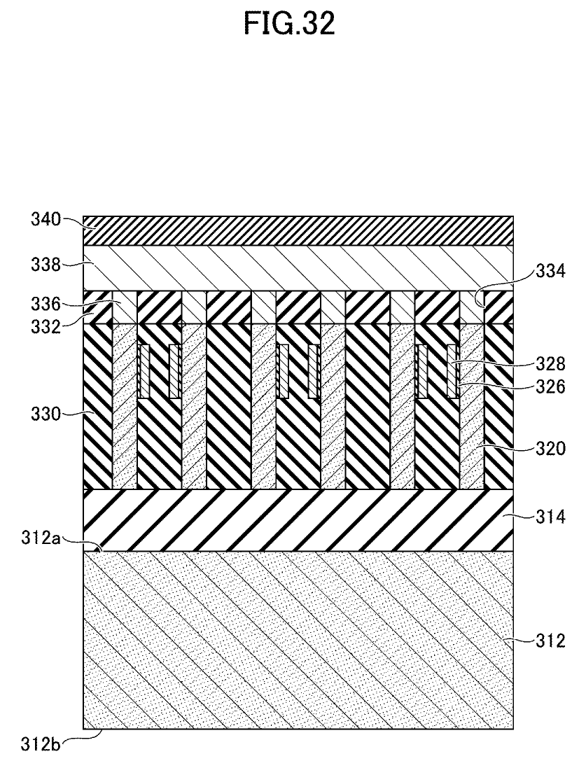

Next, as illustrated in FIG. 32, the bit line 338 is formed. In the present embodiment, first, an insulating film for the interlayer insulating film 332 is formed over the crystal silicon film 320 and the interlayer insulating film 330. The insulating film for the interlayer insulating film 332 is, for example, an SiO₂ film, an SiOCN film, or an SiOC film. Next, a resist mask including an opening is formed over the crystal silicon film 320 through lithography. Next, the insulating film for the interlayer insulating film 332 is etched and removed through dry etching or the like using the resist mask. This forms a via 334 from which the crystal silicon film 320 is exposed. Next, a metal film is formed such that the via 334 is embedded, and the surface is planarized through CMP or the like. As a result, a metal film 336 is formed in the via 334. The metal film 336 is formed, for example, of titanium nitride, tungsten, cobalt, molybdenum, or ruthenium. Next, an insulating film for an interlayer insulating film (not shown) for insulation between the bit lines 338 is formed over the interlayer insulating film 332 and the metal film 336. The insulating film for the interlayer insulating film is, for example, an SiO₂ film, an SiOCN film, or an SiOC film. Next, a resist mask including an opening in a region where the bit line 338 is to be formed is formed through lithography. Next, the insulating film for the interlayer insulating film is etched through dry etching or the like using the resist mask. This forms a trench from which the interlayer insulating film 332 and the metal film 336 are exposed. Next, a metal film for the bit line 338 is formed such that the trench is embedded, and the surface is planarized through CMP or the like. This forms the bit line 338 in the trench. The bit line 338 is formed of titanium nitride, tungsten, cobalt, molybdenum, or ruthenium. Next, an interlayer insulating film 340 is formed over the bit line 338 and the interlayer insulating film for insulation between the bit lines 338. The interlayer insulating film 340 is, for example, an SiO₂ film, an SiOCN film, or an SiOC film.

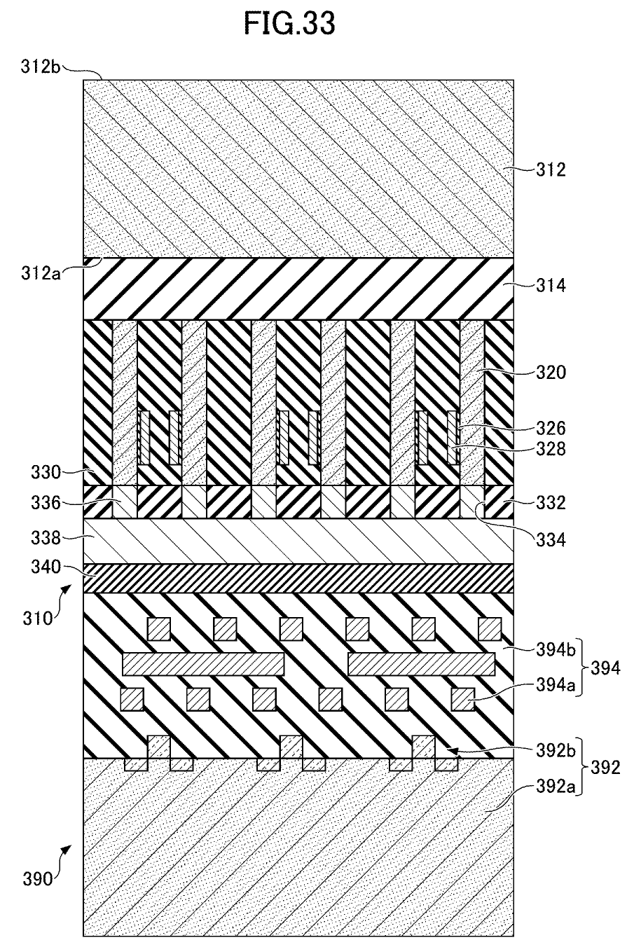

Next, as illustrated in FIG. 33, the first main surface 312a of the first substrate 310, over which up to the interlayer insulating film 340 is formed, is bonded to a second substrate 390 that is previously provided. In the present embodiment, the second substrate 390 is a CMOS substrate. The second substrate 390 includes a CMOS portion 392 and an interconnect portion 394. The CMOS portion 392 includes a silicon substrate 392a and a plurality of transistors 392b. The plurality of transistors 392b include a P-type transistor and an N-type transistor. The interconnect portion 394 includes an interconnect 394a and an interlayer insulating film 394b. The interconnect 394a is formed into a multilayer structure. The interlayer insulating film 394b insulates between the interconnects 394a. The first substrate 310 and the second substrate 390 are bonded such that the interlayer insulating film 340 and the interconnect portion 394 contact each other.

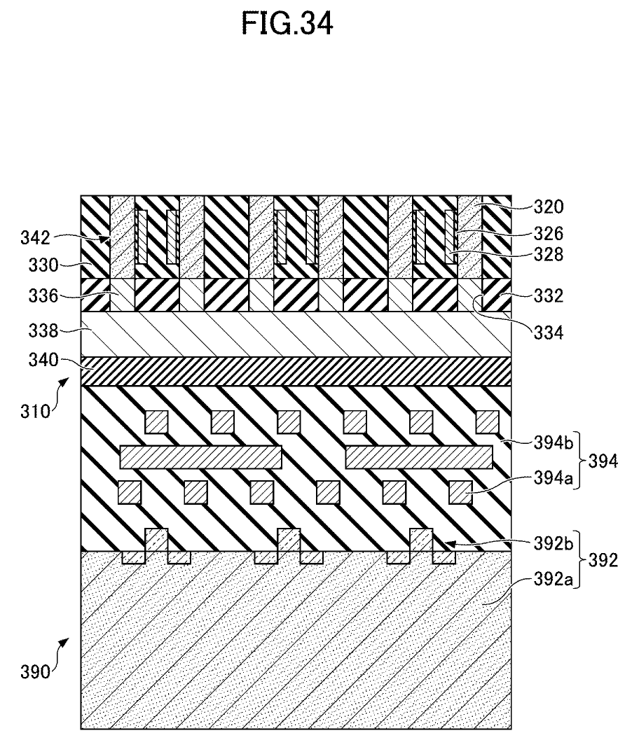

Next, as illustrated in FIG. 34, the silicon substrate 312, the silicon oxide film 314, a portion of the crystal silicon film 320, and a portion of the interlayer insulating film 330 are removed from the second main surface 312b side of the silicon substrate 312, thereby thinning the first substrate 310. In the present embodiment, first, grinding and CMP are sequentially performed to polish and remove the silicon substrate 312, the silicon oxide film 314, the portion of the crystal silicon film 320, and the portion of the interlayer insulating film 330 from the second main surface 312b side. In this case, a metal, which can diffuse into the silicon oxide film 314, is removed along with the silicon oxide film 314, and thus is not left in the semiconductor device 3, which is a final product. In the case of polishing the portion of the crystal silicon film 320, the crystal silicon film 320 is polished up to the vicinity of the gate electrode 328 to reduce the film thickness of the crystal silicon film 320. In this case, a region in the vicinity of the end point of metal-induced crystallization or metal-induced lateral crystallization in the crystal silicon film 320 is removed. In the region in the vicinity of the end point of metal-induced crystallization or metal-induced lateral crystallization, crystallinity tends to deteriorate or crystallinity tends to be non-uniform. Therefore, by removing the region in the vicinity of the end point of metal-induced crystallization or metal-induced lateral crystallization, the crystal silicon film 320 with good crystallinity can be used as a channel. Next, ion implantation is performed on a capacitor 360 side of the crystal silicon film 320. For example, a drain region (not shown) is formed through the ion implantation. This forms a transistor 342 including a channel (not shown) between the source region and the drain region of the crystal silicon film 320. In the ion implantation for forming the drain region, n-type impurities, such as arsenic, phosphorus, or the like, are ion-implanted. The drain region is electrically connected to the capacitor 360. Next, activation annealing is performed through RTA, a heating furnace, or the like.

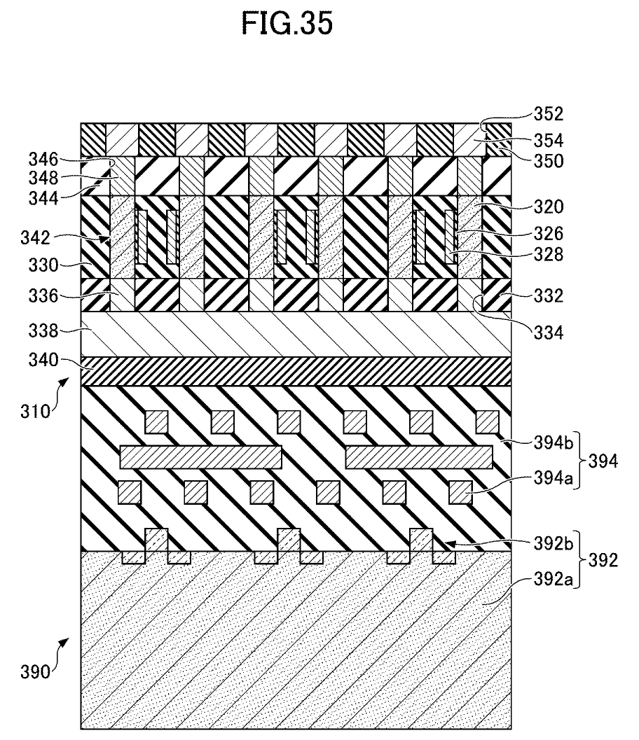

Next, as illustrated in FIG. 35, a pad 354 for the capacitor 360 is formed. In the present embodiment, first, an insulating film for the interlayer insulating film 344 is formed over the crystal silicon film 320 and the interlayer insulating film 330. The insulating film for the interlayer insulating film 344 is, for example, an SiO₂ film, an SiOCN film, or an SiOC film. Next, a resist mask including an opening is formed over the crystal silicon film 320 through lithography. Next, the insulating film for the interlayer insulating film 344 is etched and removed through dry etching or the like using the resist mask. This forms a via 346 from which the crystal silicon film 320 is exposed. Next, a metal film is formed such that the via 346 is embedded, and the surface is planarized through CMP or the like. This forms a metal film 348 inside the via 346. The metal film 348 is formed, for example, of titanium nitride, tungsten, cobalt, molybdenum, or ruthenium. Next, an insulating film for an interlayer insulating film 350 is formed over the interlayer insulating film 344 and the metal film 348. The insulating film for the interlayer insulating film 350 is, for example, an SiO₂ film, an SiOCN film, or an SiOC film. Next, a resist mask including an opening is formed over the metal film 348 through lithography. Next, the insulating film for the interlayer insulating film 350 is etched and removed through dry etching or the like using the resist mask. This forms an opening 352 from which the metal film 348 is exposed. Next, a metal film is formed such that the opening 352 is embedded, and the surface is planarized through CMP or the like. This forms the pad 354 inside the opening 352. The pad 354 is formed, for example, of titanium nitride, tungsten, cobalt, molybdenum, or ruthenium.

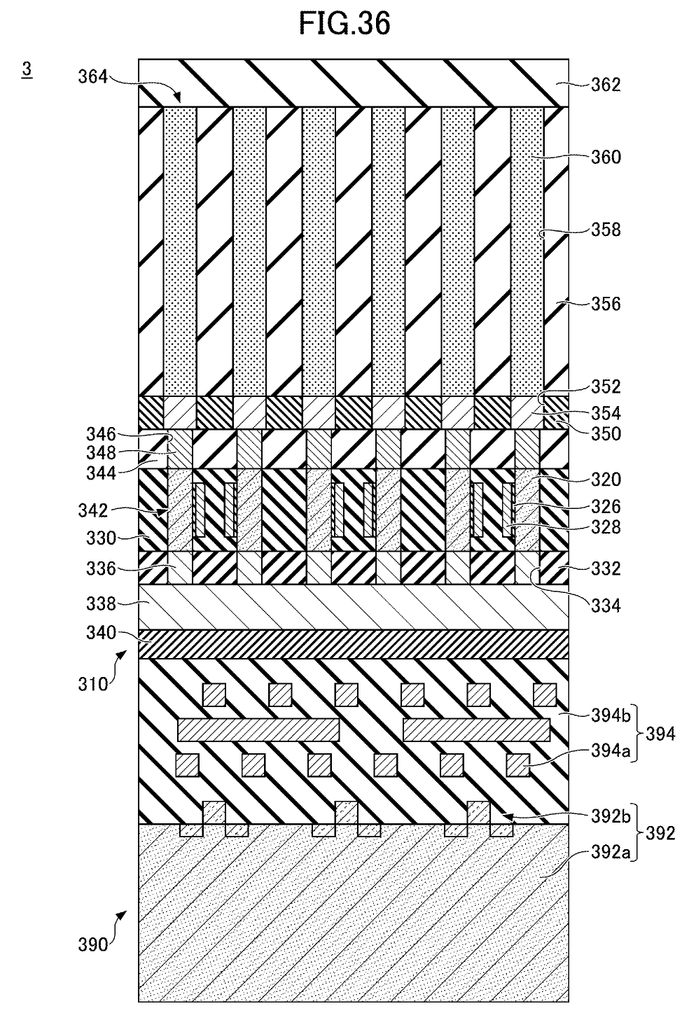

Next, as illustrated in FIG. 36, the capacitor 360 is formed that is next to the transistor 342 in the direction perpendicular to the first main surface 312a, and is electrically connected to the transistor 342. In the present embodiment, first, an insulating film for an interlayer insulating film 356 is formed over the interlayer insulating film 350 and the pad 354. The insulating film for the interlayer insulating film 356 is, for example, an SiO₂ film, an SiOCN film, or an SiOC film. Next, a resist mask including an opening is formed over the pad 354 through lithography. Next, the insulating film for the interlayer insulating film 356 is etched and removed through dry etching or the like using the resist mask. This forms a capacitor hole 358 from which the pad 354 is exposed. Next, the capacitor 360 is formed inside the capacitor hole 358. The capacitor 360 has, for example, a structure in which an insulating film is sandwiched between metal films. Next, an insulating film 362 covering the upper surface of the interlayer insulating film 356 and the upper surface of the capacitor 360 is formed.

Through the above process, the semiconductor device 3 according to the third embodiment is produced. The semiconductor device 3 is configured as a DRAM including a plurality of memory cells 364. Each memory cell 364 includes the transistor 342 and the capacitor 360 that are connected in series.

As described above, according to the production method of the semiconductor device 3 according to the third embodiment, first, the silicon substrate 312 including the first main surface 312a is provided. Next, the silicon oxide film 314, the amorphous silicon film 316, and the metal layer 318 are sequentially formed over the first main surface 312a of the silicon substrate 312. Next, the amorphous silicon film 316 is changed into the crystal silicon film 320 by annealing the silicon substrate 312 over which the metal layer 318 is formed. Next, the transistor 342 using a portion of the crystal silicon film 320 as a channel is formed. Next, the capacitor 360 is formed that is next to the transistor 342 in the direction perpendicular to the first main surface 312a, and is electrically connected to the transistor 342. In this case, the semiconductor device 3 including the transistor 342 using a portion of the crystal silicon film 320 as a channel can be formed without using an SOI substrate.

According to the production method of the semiconductor device 3 according to the third embodiment, the region in the vicinity of the starting point of metal-induced crystallization or metal-induced lateral crystallization and the region in the vicinity of the end point of metal-induced crystallization or metal-induced lateral crystallization are removed from the crystal silicon film 320. In this case, the crystal silicon film 320 with good crystallinity can be used as a channel.

According to the present disclosure, it is possible to form a semiconductor device including a transistor using a portion of a crystal silicon film as a channel, without using an SOI substrate.

The embodiments disclosed herein should be considered exemplary and not restrictive in all respects. Omissions, substitutions, or modifications are possible in the above embodiments in various ways without departing from the scope and intent of claims recited.

1. A production method of a semiconductor device, the production method comprising:
providing a silicon substrate including a first main surface;
forming a silicon oxide film over the first main surface of the silicon substrate;
forming an amorphous silicon film over the silicon oxide film;
forming a metal layer over the amorphous silicon film;
changing the amorphous silicon film into a crystal silicon film by annealing the silicon substrate over which the metal layer is formed;
forming a transistor using a portion of the crystal silicon film as a channel; and
forming a capacitor next to the transistor as viewed in a direction perpendicular to the first main surface, the capacitor being electrically connected to the transistor.

2. The production method of the semiconductor device according to claim 1, wherein
the formation of the transistor includes:
bonding the silicon substrate to a second silicon substrate with the first main surface facing the second silicon substrate, and
after the bonding, removing the silicon substrate and the silicon oxide film.

3. The production method of the semiconductor device according to claim 2, wherein
the second silicon substrate is a complementary metal oxide semiconductor (CMOS) substrate.

4. The production method of the semiconductor device according to claim 3, wherein
the crystal silicon film includes:
a first surface in contact with the silicon oxide film, and
a second surface opposite to the first surface, and
the formation of the transistor includes:
polishing the second surface of the crystal silicon film to reduce a film thickness of the crystal silicon film.

5. The production method of the semiconductor device according to claim 4, wherein
the formation of the transistor includes:
after the removal of the silicon substrate and the silicon oxide film, polishing the first surface of the crystal silicon film to reduce a film thickness of the crystal silicon film.

6. The production method of the semiconductor device according to claim 2, wherein
the removal of the silicon substrate and the silicon oxide film includes:
removing the silicon substrate through laser lift-off or a separation technique using a laser.

7. The production method of the semiconductor device according to claim 1, further comprising:
between the change into the crystal silicon film and the formation of the transistor, processing the crystal silicon film into a columnar shape extending in the direction perpendicular to the first main surface.

8. The production method of the semiconductor device according to claim 1, further comprising:
between the formation of the amorphous silicon film and the formation of the metal layer, processing the amorphous silicon film into a columnar shape extending in the direction perpendicular to the first main surface.

9. The production method of the semiconductor device according to claim 8, further comprising:
between the processing into the columnar shape and the formation of the metal layer, forming a gettering film covering a side surface of the amorphous silicon film.

10. The production method of the semiconductor device according to claim 9, further comprising:
after the formation of the metal layer, removing the gettering film.
